(19) United States
(12) Patent Application Publication
(10) Pub. No.: US 2026/0023117 A1
(43) Pub. Date: Jan. 22, 2026

(54) TEST CIRCUIT, TEST APPARATUS AND TEST METHOD

(71) Applicant: ADVANTEST CORPORATION, Tokyo (JP)

(72) Inventors: Kensuke SOEDA, Saitama (JP); Yusuke ASADA, Saitama (JP); Tomohiro UENO, Saitama (JP); Bernhard ROTH, Boeblingen (DE); Henriette OSSOINIG, Munich (DE)

(21) Appl. No.: 19/266,197

(22) Filed: Jul. 11, 2025

(30) Foreign Application Priority Data
Jul. 11, 2024 (JP) 2024-111486
Aug. 15, 2024 (JP) 2024-135780

(51) Int. Cl. G01R 31/319; G01R 31/317

(52) U.S. Cl. CPC G01R 31/31924; G01R 31/31721

(57) ABSTRACT

Provided is a testing circuit including a voltage supply unit which generates an output voltage, a pulse generation unit which generates a pulse signal by using the output voltage from the voltage supply unit in a functional test of a device under test and supplies the pulse signal to a device under test, and a measurement circuit which adjusts a voltage or a current supplied to a device under test in a voltage application current measurement test or a current application voltage measurement test of a device under test to a test voltage or a test current and performs the voltage application current measurement test or the current application voltage measurement test by using the test voltage or the test current, in which the measurement circuit is connected at least between the voltage supply unit and the pulse generation unit.

The contents of the following patent application(s) are incorporated herein by reference:
NO. 2024-135780 filed in JP on Aug. 15, 2024
NO. 2024-111486 filed in JP on Jul. 11, 2024.

### BACKGROUND

### 1. Technical Field

The present invention relates to a testing circuit, a testing apparatus, and a testing method.

### 2. Related Art

Patent document 1 or the like describes “The ATE system 150 of this embodiment is connected to a device under test (DUT) 160 to be tested, and includes a DUT power supply (DPS) 170, pin electronics (PE) 180, a parametric measurement unit (PMU) 190, and a controller 200.” (lines 60 to 65 in the sixth column of Cited Document 1).

### Related Art Documents

### Patent Documents

Patent Document 1: U.S. Pat. No. 9,851,401

Patent Document 2: U.S. Pat. No. 7,480,583

### BRIEF DESCRIPTION OF THE DRAWINGS

FIG. 1 illustrates a configuration of a testing apparatus 1 according to an embodiment together with a device under test 10.

FIG. 2 illustrates a configuration of a pin electronics apparatus 200 according to a comparative example of the embodiment.

FIG. 3 illustrates a configuration of a pin electronics apparatus 300 according to the embodiment.

FIG. 4 illustrates an operational flow of a functional test of the device under test 10 by the testing apparatus 1 according to the embodiment while focusing on an operation of the pin electronics apparatus 300 of FIG. 3.

FIG. 5 illustrates an operational flow of a voltage application current measurement test of the device under test 10 by the testing apparatus 1 according to the embodiment while focusing on the operation of the pin electronics apparatus 300 of FIG. 3.

FIG. 6 illustrates an operational flow of a current application voltage measurement test of the device under test 10 by the testing apparatus 1 according to the embodiment while focusing on the operation of the pin electronics apparatus 300.

FIG. 7 illustrates a configuration of a pin electronics apparatus 400 according to a modified example.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

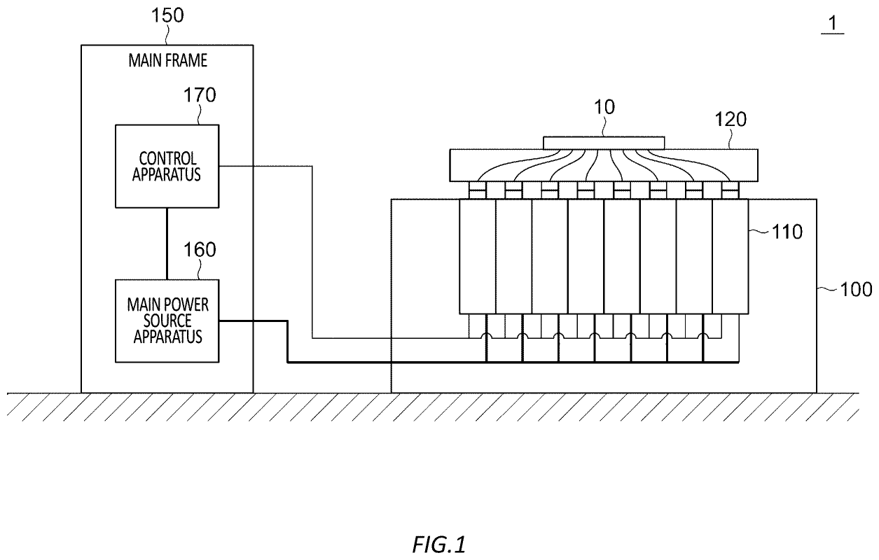

FIG. 1 illustrates a configuration of a testing apparatus 1 according to the present embodiment together with a device under test (DUT) 10. The device under test 10 is a device in which a circuit subjected to a test by the testing apparatus 1 is formed. The device under test 10 may be a wafer in which circuits are formed, an IC/LSI chip obtained by singulation of the wafer, an IC/LSI chip package in which the IC/LSI chip is packaged, or the like. In an example of this drawing, the testing apparatus 1 has the single device under test 10 mounted thereto, but instead of this, the testing apparatus 1 may have a plurality of devices under test 10 mounted thereto to simultaneously perform tests.

The testing apparatus 1 performs an electrical test of the device under test 10. Instead of this, or in addition to this, the testing apparatus 1 may perform an optical input/output test of the device under test 10. In the present embodiment, a case where the testing apparatus 1 performs the electrical test of the device under test 10 will be described as an example. When the testing apparatus 1 performs the optical input/output test of the device under test 10, the testing apparatus 1 and the device under test 10 may be connected through an optical connection in addition to an electrical connection.

The testing apparatus 1 includes a test head 100, a plurality of pin electronics apparatuses 110, a connection apparatus 120, and a main frame 150. The test head 100 is an enclosure in which the plurality of pin electronics apparatuses 110 can be mounted. In an example of this drawing, the test head 100 has a plurality of slots into which the plurality of pin electronics apparatuses 110 are inserted.

Each of the plurality of pin electronics apparatuses 110 is inserted into the slot of the test head 100 and detachably connected to a back plane of the test head 100. The pin electronics apparatus 110 may also be referred to as a “pin electronics card”, a “tester board”, a “test module”, or the like. Each of the pin electronics apparatuses 110 is electrically connected to the device under test 10 via the connection apparatus 120. Each of the pin electronics apparatuses 110 performs input and output of a signal with the device under test 10 and tests the device under test 10 by examining a signal input from the device under test 10.

The connection apparatus 120 is mounted to the test head 100 and electrically connected to the plurality of pin electronics apparatuses 110. The connection apparatus 120 has the device under test 10 mounted thereto and is electrically connected to a plurality of terminals included in the device under test 10. The connection apparatus 120 has a role of serving as an interface for mutual terminals between the plurality of pin electronics apparatuses 110 and the device under test 10 and electrically connects each terminal of one or more devices under test 10 and a corresponding terminal of the plurality of pin electronics apparatuses 110 through a signal cable, a substrate wiring, or the like.

The main frame 150 controls each unit in the testing apparatus 1 to perform a test of the device under test 10. In the present embodiment, the main frame 150 is an enclosure different from the enclosure in which the test head 100 and the like are provided. Instead of this, each configuration in the main frame 150 may be provided in a same enclosure as that for the test head 100. The main frame 150 has a main power source apparatus 160 and a control apparatus 170.

The main power source apparatus 160 receives power supply from a commercial power source or the like and supplies power to each of apparatuses, circuits, and the like in the testing apparatus 1. The control apparatus 170 is connected to the main power source apparatus 160 to receive power supply from the main power source apparatus 160. The control apparatus 170 controls the test of the device under test 10. The control apparatus 170, when achieved by a computer, may control the test of the device under test 10 by executing a test control program. The control apparatus 170 supplies a test program to each of the pin electronics apparatuses 110 and causes the supplied test program to be executed by each of the pin electronics apparatuses 110 to cause the device under test 10 to be tested. The control apparatus 170 collects and records a test result of the device under test 10 from each of the pin electronics apparatuses 110.

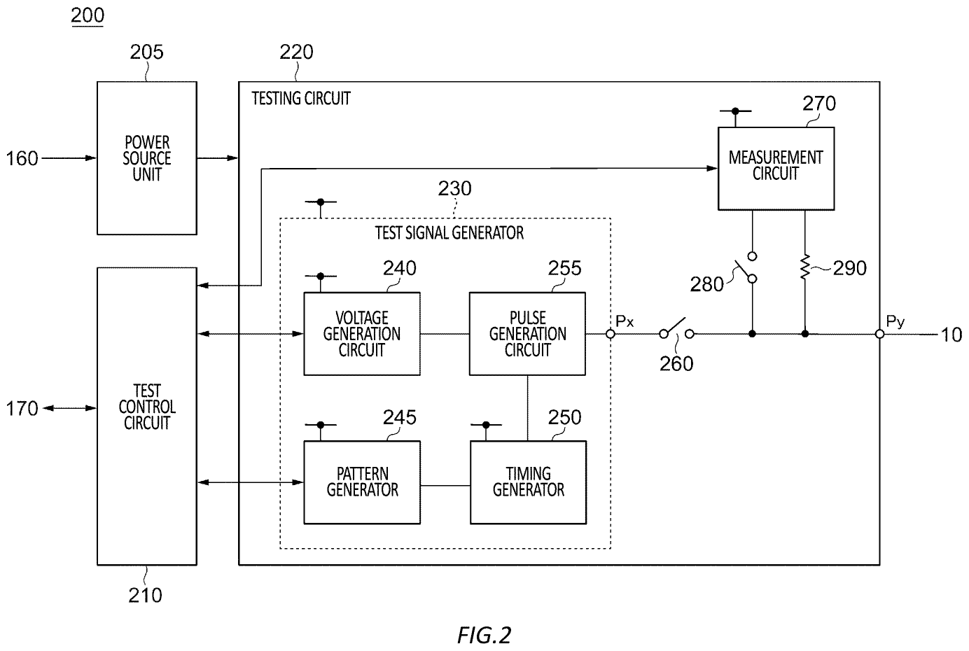

FIG. 2 illustrates a configuration of a pin electronics apparatus 200 according to a comparative example of the present embodiment. The pin electronics apparatus 200 according to the comparative example may be used as the pin electronics apparatus 110 in the testing apparatus 1. The pin electronics apparatus 200 includes a power source unit 205, a testing circuit 220, and a test control circuit 210.

The power source unit 205 receives power supply from the main power source apparatus 160 to generate power to be supplied to each circuit in the pin electronics apparatus 200 and supplies power to each circuit in the pin electronics apparatus 200. The power source unit 205 may have a plurality of power sources and output power of a plurality of types in which rated voltages, rated currents, or the like are different from each other.

The testing circuit 220 is connected to the device under test 10 via the connection apparatus 120, receives power supply from the power source unit 205, and tests the device under test 10. This drawing illustrates a circuit portion corresponding to a single terminal of the device under test 10 in the testing circuit 220 in a representative manner. The testing circuit 220 may be connected to a plurality of terminals and have a circuit portion corresponding to each of the terminals.

The testing circuit 220 may have a connection terminal Py (also simply referred to as a terminal Py) for the device under test 10 and may be connected to the device under test 10 via the terminal Py. The testing circuit 220 has a test signal generator 230 to perform an operational test (also represented as a functional test) of the device under test 10.

The test signal generator 230 receives power supply from the power source unit 205 and control by the test control circuit 210 to generate a test signal to be supplied to the device under test 10 in the functional test of the device under test 10 and supplies the test signal to the terminal of the device under test 10. Herein, the test signal generated by the test signal generator 230 may be a pulse signal having a desired signal pattern such as a digital signal or a multi-value signal that is to be supplied to the device under test 10.

The test signal generator 230 has a voltage generation circuit 240, a pattern generator 245, a timing generator 250, and a pulse generation circuit 255. The voltage generation circuit 240 is an example of a voltage supply unit and generates an output voltage. The voltage generation circuit 240 may receives power supply from the power source unit 205 and control by the test control circuit 210 to generate a power source voltage required by the pulse generation circuit 255 in the functional test as the output voltage. The voltage generation circuit 240 may supply, to the pulse generation circuit 255, a power source voltage according to a voltage at high level in a pulse signal that is to be supplied to the terminal of the device under test 10 as the output voltage.

The pattern generator 245 receives power supply from the power source unit 205 and control by the test control circuit 210 and generates a test pattern which designates a waveform of the pulse signal that is to be supplied to the terminal of the device under test 10 in the functional test. The pattern generator 245 may execute a test command for each test cycle which has a predetermined period and output the test pattern associated with the test command. The test pattern for each test cycle designates a change pattern of the test signal in the test cycle. The pattern generator 245 may be possible to designate, although it varies depending on a model, a pattern identifier representing a waveform shape such as, for example, return to zero (RZ) or non return to zero (NRZ), a polarity of the waveform shape, and the like as the change pattern of such a test signal.

The timing generator 250 receives power supply from the power source unit 205 and control by the test control circuit 210 and generates a change timing of the pulse signal that is to be supplied to the terminal of the device under test 10 in the functional test. The timing generator 250 generates a waveform of the pulse signal that is to be supplied to the device under test 10 by imparting the change timing in real time to the change pattern of the test signal for each test cycle. Note that depending on a model of the testing apparatus 1, the pattern generator 245 may generate a test pattern for each test cycle, the timing generator 250 may generate a timing for each test cycle, and a waveform shaper may shape a waveform of the pulse signal that is to be supplied to the device under test 10 by using the timing by the timing generator 250.

The pulse generation circuit 255 is an example of a pulse generation unit and generates a pulse signal by using the output voltage from the voltage generation circuit 240 in the functional test of the device under test 10 to supply the pulse signal to the device under test 10. The pulse generation circuit 255 may receive the output voltage from the voltage generation circuit 240 and generate the pulse signal by using the output voltage from the voltage generation circuit 240 in the functional test to supply the pulse signal to the terminal of the device under test 10. The pulse generation circuit 255 may drive an output according to the waveform of the test signal to which the change timing in real time has been imparted for each test cycle to high level or low level (in a binary case) or drive the output to each of the multi-value levels to output a pulse signal obtained by changing the test pattern created by the pattern generator 245 at the timing created by the timing generator 250.

The test signal generator 230 illustrated above may be achieved by a set of a discrete IC, an LSI, or an ASIC or may be achieved by a single test signal generation ASIC. The test signal generator 230 may further have a function of receiving a response signal output by the device under test 10 according to the test signal and determining pass or fail or the like of the device under test 10. In this case, the test signal generator 230 may have a comparator which compares the response signal from the device under test 10 with a target value and a determinator which determines pass or fail of the device under test 10 by using a comparison result by the comparator.

A relay 260 is provided between a terminal Py of the testing circuit 220 which is connected to the terminal of the device under test 10 and the test signal generator 230. The relay 260 may be a mechanical relay or may be a semiconductor relay using a semiconductor switch or the like. The relay 260 is turned on by the test control circuit 210 or the like when the functional test of the device under test 10 is performed, and connects the test signal generator 230 and the terminal of the device under test 10. On the other hand, the relay 260 is turned off by the test control circuit 210 or the like when a parametric test (a voltage application current measurement test, a current application voltage measurement test, or the like) of the device under test 10 by a measurement circuit 270 is performed, and disconnects the test signal generator 230 and the terminal of the device under test 10.

The measurement circuit 270 is connected to a wiring between a terminal from which the test signal generator 230 outputs the pulse signal and the terminal of the device under test 10. In an example of this drawing, the measurement circuit 270 is connected to a force line through which a voltage or a current is applied to the terminal of the device under test 10 via a relay 280 and a sense line for sensing a voltage of the terminal of the device under test 10 via a resistance 290. The force line and the sense line are connected to a wiring between the relay 260 and the terminal Py of the testing circuit 220 connected to the terminal of the device under test 10.

The measurement circuit 270 receives power supply from the power source unit 205 and control by the test control circuit 210 and performs the parametric test of the device under test 10. Depending on a model, as an example, the measurement circuit 270 may include various circuits including at least one of a voltage generator which generates a voltage to be supplied to the terminal of the device under test 10, a current generator which generates a current to be supplied to the device under test 10, a voltage measuring instrument which measures a voltage output by the device under test 10, a current measuring instrument which measures a current output by the device under test 10, a frequency measuring instrument which measures a frequency of a signal output by the device under test 10, or the like. In an example of this drawing, the measurement circuit 270 is provided in the pin electronics apparatus 200. Instead of this, the measurement circuit 270 may be achieved by another pin electronics apparatus 110 in the testing apparatus 1.

When the voltage application current measurement test is performed, the measurement circuit 270 outputs a desired test voltage via the force line and measures a current which flows through the terminal of the device under test 10 which has received the test voltage. When the current application voltage measurement test is performed, the measurement circuit 270 causes a desired test current to flow between the measurement circuit 270 and the terminal of the device under test 10 via the force line and measures the voltage of the terminal of the device under test 10 via the sense line.

The relay 280 is provided in a force line between the measurement circuit 270 and a connection point on a terminal Py side relative to the relay 260 in a wiring between the terminal Py of the testing circuit 220 and the test signal generator 230. The relay 280 may be a mechanical relay or may be a semiconductor relay using a semiconductor switch or the like. The relay 280 is turned off by the test control circuit 210 or the like when the functional test of the device under test 10 is performed, and disconnects the measurement circuit 270 and the terminal of the device under test 10. The relay 280 is turned on by the test control circuit 210 or the like when the parametric test of the device under test 10 is performed, and connects the measurement circuit 270 and the terminal of the device under test 10.

The resistance 290 is provided in a sense line between the measurement circuit 270 and the connection point on the terminal Py side relative to the relay 260 in the wiring between the terminal Py of the testing circuit 220 and the test signal generator 230. The resistance 290 may be a relatively large resistance such as, for example 10 KΩ, and allows the voltage of the terminal of the device under test 10 to be input to the measurement circuit 270 while the terminal of the device under test 10 and the measurement circuit 270 are substantially isolated.

The test control circuit 210 controls a test of the device under test 10 by the testing circuit 220. The test control circuit 210 may be also referred to as a “site controller”. By executing a test program supplied from the control apparatus 170 and controlling each unit in the testing circuit 220, the test control circuit 210 causes the testing circuit 220 to perform a test such as the operational test or the parametric test of the device under test 10.

In the pin electronics apparatus 200 described above, the measurement circuit 270 is connected to a wiring between a terminal Px from which the test signal generator 230 outputs a pulse signal and the terminal of the device under test 10. In the functional test of the device under test 10, a high speed pulse signal is transmitted through the wiring between the terminal Px of the test signal generator 230 and the terminal of the device under test 10. Herein, the relay 260 is set to be on, and the relay 280 is set to be off in the functional test of the device under test 10, but the relay 260 has a parasitic capacitance even when it is on, and the relay 280 has a parasitic capacitance even when it is off. Thus, the wiring between the terminal Px of the test signal generator 230 and the terminal of the device under test 10 causes RC delay by the parasitic capacitances of the relay 260 and the relay 280, and transmission of the high speed pulse signal is disrupted.

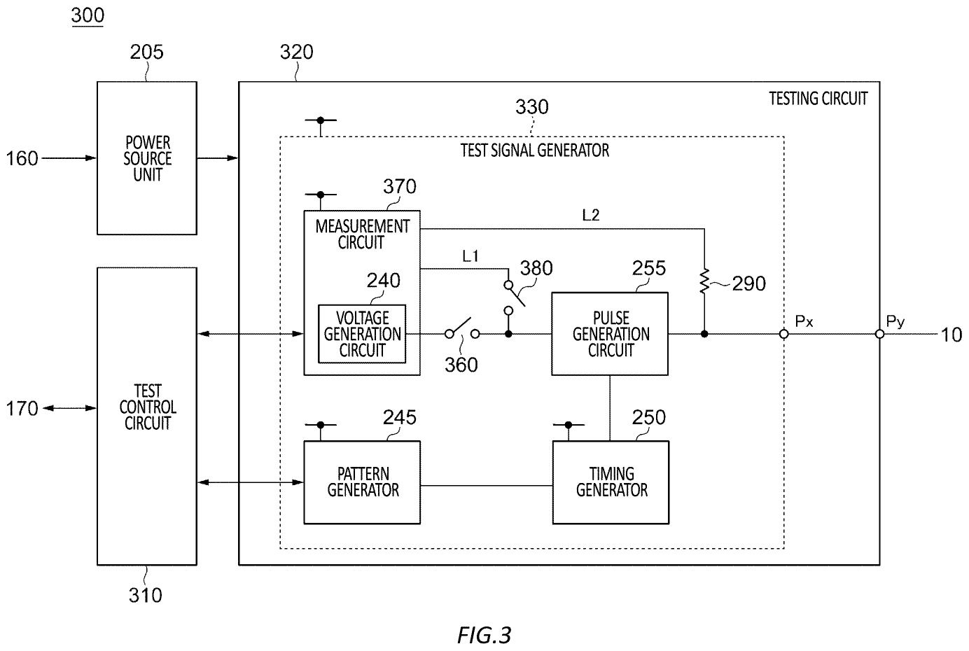

FIG. 3 illustrates a configuration of a pin electronics apparatus 300 according to the present embodiment. The pin electronics apparatus 300 is a modified example of the pin electronics apparatus 200. The testing apparatus 1 may include a pin electronics apparatus 300 instead of the pin electronics apparatus 200. The pin electronics apparatus 300 has the power source unit 205, a testing circuit 320, and a test control circuit 310. In this drawing, components with same reference numerals as those in FIG. 2 have similar functions and configurations to those in FIG. 2 and therefore will not be described below except for differences.

A testing circuit 320 is connected to the device under test 10 via the connection apparatus 120, receives power supply from the power source unit 205, and tests the device under test 10. This drawing illustrates a circuit portion corresponding to a single terminal of the device under test 10 in the testing circuit 320 in a representative manner. The testing circuit 320 may be connected to a plurality of terminals and have a circuit portion corresponding to each of the terminals.

The testing circuit 320 has a test signal generator 330. The test signal generator 330 according to the present embodiment receives power supply from the power source unit 205 and control by a test control circuit 310 and performs both the functional test and the parametric test of the device under test 10. The testing circuit 320 may perform both the functional test and the parametric test on the same device under test 10 according to a use method by a user. The testing circuit 320 may perform the functional test on a certain device under test 10 and perform the parametric test on a different device under test 10. In addition, depending on the use method of the user, the testing circuit 320 may perform only one of the functional test or the parametric test, and a function of performing the other test does not necessarily need to be used. The test signal generator 330 has a measurement circuit 370, the pattern generator 245, the timing generator 250, the pulse generation circuit 255, and the resistance 290.

The measurement circuit 370 is connected at least between the voltage generation circuit 240 and the pulse generation circuit 255. Being connected between the voltage generation circuit 240 and the pulse generation circuit 255 may be being connected to a wiring between the voltage generation circuit 240 and the pulse generation circuit 255. The measurement circuit 370 according to the present embodiment is configured by having the voltage generation circuit 240, and may be connected to a wiring which connects the voltage generation circuit 240 and the pulse generation circuit 255 and a wiring which connects the pulse generation circuit 255 and the device under test 10 in addition to being connected to the pulse generation circuit 255 from the voltage generation circuit 240. According to the present embodiment, as an example, the measurement circuit 370 is connected between the voltage generation circuit 240 and the pulse generation circuit 255 and between the pulse generation circuit 255 and the device under test 10 via a first line L1 (also referred to as a force line L1) through which a voltage or a current is to be supplied to the device under test 10 and a second line L2 (also referred to as a sense line L2) through which a voltage of the device under test 10 is to be measured.

The force line L1 may be connected to the measurement circuit and connected between the voltage generation circuit 240 and the pulse generation circuit 255. The force line L1 may function as an input end feedback line to feed back a voltage on an input end side of the pulse generation circuit 255 to the measurement circuit 370. In this case, the measurement circuit 370 may adjust an output voltage by using a voltage fed back from the force line in the functional test. Note that a resistance similar to the resistance 290 illustrated in FIG. 2 may be provided in the force line L1.

The sense line L2 may be connected to the measurement circuit 370 and connected between the pulse generation circuit 255 and the device under test 10. The sense line L2 may have a function similar to the sense line of the voltage illustrated in FIG. 2, and is connected to a connection point on a wiring between an output end of the pulse generation circuit 255 and the terminal of the device under test 10 and feeds back a voltage at this connection point to the measurement circuit 370. This connection point may be provided near the output end of the pulse generation circuit 255 in the test signal generator 330. Instead of this, this connection point may be provided outside the test signal generator 330 in the testing circuit 320, and for example, may be provided outside the testing circuit 320 near a terminal of the device under test 10 or the like. The resistance 290 having the function and the configuration similar to those of the resistance 290 illustrated in FIG. 2 may be provided in the force line L1.

The measurement circuit 370 adjusts a voltage or a current supplied to the device under test 10 in the parametric test (the voltage application current measurement test, the current application voltage measurement test, or the like) of the device under test 10 to a test voltage or a test current and performs the parametric test by using the test voltage or the test current. The adjustment of the voltage or the current supplied to the device under test 10 to the test voltage or the test current may be an adjustment of the voltage or the current supplied towards the device under test 10 such that the test voltage or the test current is applied to the device under test 10.

The measurement circuit 370 according to the present embodiment may share the voltage generation circuit 240 with the pulse generation circuit 255 and may adjust the test voltage or the test current by using a voltage supplied from the voltage generation circuit 240. According to the present embodiment, as an example, the measurement circuit 370 is configured by having the voltage generation circuit 240 and adjusts an output voltage generated from the voltage generation circuit 240 to cause the test voltage or the test current to be supplied to the device under test 10.

The measurement circuit 370 may receive power supply from the power source unit 205 and control by the test control circuit 310. Although it may vary depending on a type of the supported parametric test, as an example, the measurement circuit 370 may further include various circuits including at least one of a current generator which generates a current to be supplied to the device under test 10, a voltage measuring instrument which measures a voltage output by the device under test 10, a current measuring instrument which measures a current output by the device under test 10, a frequency measuring instrument which measures a frequency of a signal output by the device under test 10, or the like.

The measurement circuit 370 according to the present embodiment may be possible to perform, as the parametric test, at least one of the voltage application current measurement test or the current application voltage measurement test. In the voltage application current measurement test, the measurement circuit 370 generates an output voltage and performs the voltage application current measurement test of the device under test 10 by using the output voltage. The output voltage of the measurement circuit 370 is supplied to the terminal of the device under test 10 as a test voltage via the pulse generation circuit 255. In the current application voltage measurement test, the measurement circuit 370 generates an output current and performs the current application voltage measurement test of the device under test 10 by using this output current. The output current of the measurement circuit 370 is supplied to the terminal of the device under test 10 as a test current via the pulse generation circuit 255. Herein, the output current of the measurement circuit 370 may be a positive current, that is, a current (source current) which flows towards the terminal of the device under test 10 from the measurement circuit 370 or may be a negative current, that is, a current (sink current) which flows towards the measurement circuit 370 from the terminal of the device under test 10.

The voltage generation circuit 240 of the measurement circuit 370 generates, as an output voltage, a power source voltage required by the pulse generation circuit 255 in the functional test. The voltage generation circuit 240 may supply, to the pulse generation circuit 255, a power source voltage according to a voltage at high level in a pulse signal that is to be supplied to the terminal of the device under test 10 as the output voltage.

Herein, the voltage generation circuit 240 of the measurement circuit 370 may be connected in series to the pulse generation circuit 255, and a first relay 360 may be provided between the voltage generation circuit 240 and the pulse generation circuit 255. The first relay 360 may be provided on the voltage generation circuit 240 side relative to a connection point with the force line L1 in the wiring between the voltage generation circuit 240 and the pulse generation circuit 255. The first relay 360 may be a mechanical relay or may be a semiconductor relay using a semiconductor switch or the like. The first relay 360 is turned on by the test control circuit 310 or the like when the functional test of the device under test 10 is performed, and connects the voltage generation circuit 240 and the pulse generation circuit 255. On the other hand, the first relay 360 is turned off by the test control circuit 310 or the like when the parametric test (the voltage application current measurement test, the current application voltage measurement test, or the like) of the device under test 10 by the measurement circuit 370 is performed, and disconnects the voltage generation circuit 240 and the pulse generation circuit 255.

In addition, a second relay 380 may be provided between the measurement circuit 370 and a point between the pulse generation circuit 255 and the voltage generation circuit 240. The second relay 380 may be provided in the force line L1 between the measurement circuit 370 and a connection point on the pulse generation circuit 255 side relative to the first relay 360 in a wiring between the pulse generation circuit 255 and the voltage generation circuit 240. The second relay 380 may be a mechanical relay or may a semiconductor relay using a semiconductor switch or the like. The second relay 380 is turned off by the test control circuit 310 or the like when the functional test of the device under test 10 is performed, and disconnects the measurement circuit 370 and the pulse generation circuit 255. The second relay 380 is turned on by the test control circuit 310 or the like when the parametric test of the device under test 10 is performed, and connects the measurement circuit 370 and the pulse generation circuit 255.

The pattern generator 245, the timing generator 250, and the pulse generation circuit 255 have similar functions and configurations to those in the pattern generator 245, the timing generator 250, and the pulse generation circuit 255 illustrated in FIG. 2. The pulse generation circuit 255 generates a pulse signal by using the output voltage of the measurement circuit 370 in the functional test of the device under test 10 and supplies the generated pulse signal to the terminal of the device under test 10. The pulse generation circuit 255 causes the output voltage of the measurement circuit 370 to pass therethrough in the voltage application current measurement test and supplies this output voltage that has passed to the terminal of the device under test 10 as a test voltage. The pulse generation circuit 255 causes the output current of the measurement circuit 370 to pass therethrough in the current application voltage measurement test and supplies this output current that has passed as a test current to the terminal of the device under test 10. Note that the testing circuit 320 may generate a pulse signal by the pulse generation circuit 255 by using any circuit other than the pattern generator 245 and the timing generator 250.

Since the pulse generation circuit 255 has a function of outputting a digital signal or a multi-value signal in the functional test, at least one signal value (for example, high level in the digital signal or a maximum value in the multi-value signal), the pulse generation circuit 255 causes the output voltage supplied from the measurement circuit 370 to pass therethrough via at least one of a resistance or a switching device in the pulse generation circuit 255 and outputs this output voltage that has passed to the terminal of the device under test 10. Since the pulse generation circuit 255 regularly performs control to output such a signal value, the control apparatus 170 during the parametric test, the test control circuit 310, the pattern generator 245 and the timing generator 250, or the like can connect the input end and the output end of the pulse generation circuit 255 via at least one of the resistance or the switching device and supply the output voltage or the output current of the measurement circuit 370 via the pulse generation circuit 255 to the device under test 10 as the test voltage or the test current.

Herein, the pulse generation circuit 255 according to the present embodiment and the terminal Py for the device under test 10 may be electrically and fixedly connected. Being electrically and fixedly connected may be being electrically connected with the connected state fixedly maintained. Therefore, a relay configured to disconnect the connection, that is, for example, a relay (as an example, the relay 260 of FIG. 2) or the like configured to switch any of the functional test and the voltage application current measurement test or the current application voltage measurement test to be performed does not necessarily need to be present between the pulse generation circuit 255 and the terminal Py.

At least the measurement circuit 370 and the pulse generation circuit 255 which have been described above in the testing circuit 320 may be provided on a common substrate. According to the present embodiment, as an example, each unit in the test signal generator 330 may be provided on a common substrate and may be achieved by a single ASIC.

In accordance with the pin electronics apparatus 300 described above, the measurement circuit 370 which performs the parametric test by adjusting the voltage or the current supplied to the device under test 10 to the test voltage or the test current in the parametric test is connected between the voltage generation circuit 240 and the pulse generation circuit 255 which generates a pulse signal by using the output voltage from the voltage generation circuit 240 and supplies the pulse signal to the device under test 10 in the functional test. Therefore, whether the functional test is performed or the parametric test is to be performed on the device under test 10 can be switched by the switching between the voltage generation circuit 240 and the pulse generation circuit 255, that is, in a region where a high speed pulse signal does not pass therethrough. Therefore, as being different from a case where the switching is performed by switching in a region where the pulse signal passes through, it is possible to prevent inhibition of transmission by the relay terminal as a capacitance for the high speed signal and improve an accuracy of the functional test.

The terminal Py for the device under test 10 and the pulse generation circuit 255 are electrically and fixedly connected. Therefore, since a relay does not exist between the terminal Py and the pulse generation circuit 255, it is possible to certainly prevent the inhibition of the transmission of the pulse signal by the relay terminal as a capacitance for the high speed signal.

In addition, since the first relay 360 is provided between the voltage generation circuit 240 and the pulse generation circuit 255, by switching the first relay 360, whether or not to perform the functional test can be switched.

In addition, since the second relay 380 is provided between the measurement circuit 370 and the point between the pulse generation circuit 255 and the voltage generation circuit 240, by switching the second relay 380, whether or not to perform the parametric test can be switched.

In addition, the measurement circuit 370 is connected between the voltage generation circuit 240 and the pulse generation circuit 255 and connected between the pulse generation circuit 255 and the device under test 10 via the force line L1 for application of the voltage or the current to the device under test 10 and the sense line L2 for measurement of the voltage of the device under test 10. Therefore, the parametric test can be performed by performing the application of the voltage or the current to the device under test 10 from the force line L1 and the measurement in the sense line L2.

In addition, the sense line L2 for the measurement of the voltage of the device under test 10 is connected between the measurement circuit 370 and a point between the pulse generation circuit 255 and the device under test 10. Therefore, as being different from a case where the sense line L2 is connected between the voltage generation circuit 240 and the pulse generation circuit 255, a fluctuation of the measure voltage due to a resistance component of the pulse generation circuit 255 is prevented. Therefore, the voltage of the device under test 10 can be accurately measured.

In addition, since the voltage generation circuit 240 and the pulse generation circuit 255 are connected in series, as compared to a case where the voltage generation circuit 240 and the pulse generation circuit 255 are connected in parallel, the structure can be simplified for miniaturization of the testing circuit 320.

In addition, since the voltage generation circuit 240, the pulse generation circuit 255, and the measurement circuit 370 are provided on a common substrate, as compared to a case where those components are provided on separate substrates, miniaturization of the testing circuit 320 can be realized.

In addition, since the measurement circuit 370 adjusts the test voltage or the test current by using the voltage supplied from the voltage generation circuit 240, as compared to a case where a power source unit for the measurement circuit 370 is provided separately from the voltage generation circuit 240, miniaturization of the testing circuit 320 can be realized.

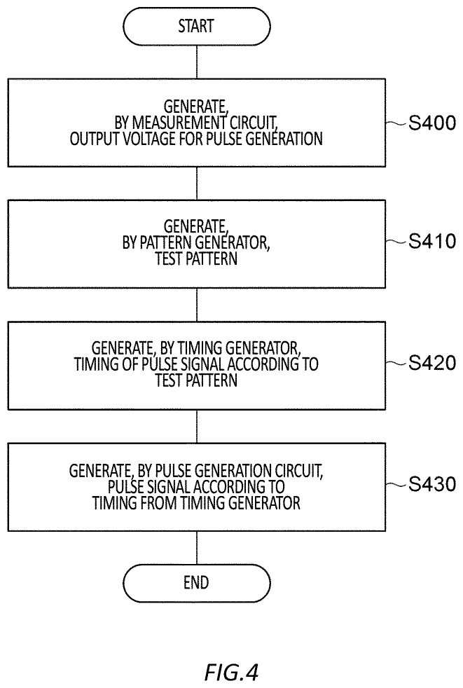

FIG. 4 illustrates an operational flow of the functional test of the device under test 10 by the testing apparatus 1 according to the present embodiment while focusing on an operation of the pin electronics apparatus 300 of FIG. 3. Before the present operational flow is started, the testing apparatus 1 electrically connects one or more pin electronics apparatuses 300 to the device under test 10 via the connection apparatus 120.

In step S400, the voltage generation circuit 240 of the measurement circuit 370 receives control of the test control circuit 310 and generates, as an output voltage, a power source voltage for pulse generation required by the pulse generation circuit 255 in the functional test. In the functional test, the measurement circuit 370 may adjust the output voltage by using a voltage fed back from the force line L1. For example, the measurement circuit 370 compares a feedback voltage fed back from the force line L1 with a target output voltage. The measurement circuit 370 increases the output voltage when the feedback voltage is lower than the target output voltage and reduces the output voltage when the feedback voltage is higher than the target output voltage. According to this, the measurement circuit 370 can adjust the output voltage to be close to the target output voltage. Note that the measurement circuit 370 may perform the feedback and adjustment of the output voltage inside the measurement circuit 370.

In S410, the pattern generator 245 receives control of the test control circuit 310 and generates a test pattern for each test cycle. In S420, the timing generator 250 receives control of the test control circuit 310 and generates a timing of a pulse signal according to the test pattern for each test cycle. In S430, the pulse generation circuit 255 generates a pulse signal according to timing from the timing generator 250 each test cycle by using the output voltage of the voltage generation circuit 240 in the measurement circuit 370 and supplies this generated pulse signal to the terminal of the device under test 10. The pin electronics apparatus 300 may receive a response signal output by the device under test 10 according to the test signal and determines pass or fail or the like of the device under test 10.

In accordance with the pin electronics apparatus 300 described above, it is possible to supply the power source voltage required in the functional test by the pulse generation circuit 255 by using the voltage generation circuit 240 in the measurement circuit 370 used for the parametric test of the device under test 10. In addition, the measurement circuit 370 can adjust the output voltage by using the feedback voltage from the force line L1 and reduce an error with the target output voltage.

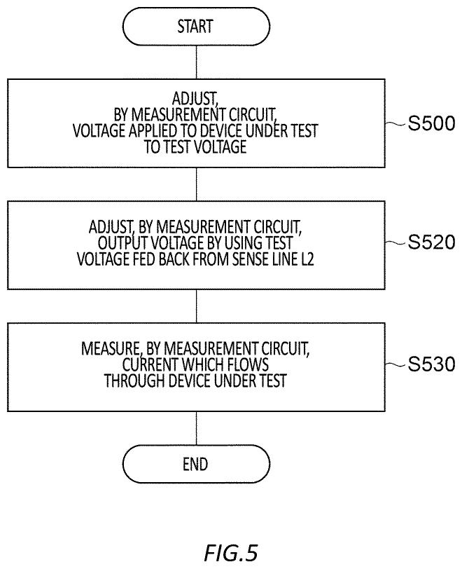

FIG. 5 illustrates an operational flow of the voltage application current measurement test of the device under test 10 by the testing apparatus 1 according to the present embodiment while focusing on an operation of the pin electronics apparatus 300 of FIG. 3. Before the present operational flow is started, the testing apparatus 1 electrically connects one or more pin electronics apparatuses 300 to the device under test 10 via the connection apparatus 120.

In S500, the voltage generation circuit 240 of the measurement circuit 370 adjusts a voltage supplied to the device under test 10 to a test voltage. As an example, the voltage generation circuit 240 of the measurement circuit 370 may generate an output voltage for the voltage application current measurement test by factoring in a voltage drop by the pulse generation circuit 255 or the like. According to this, the output voltage from the voltage generation circuit 240 passes through the pulse generation circuit 255 to become the test voltage to be supplied to the device under test 10.

In S520, the measurement circuit 370 adjusts an output voltage by using a test voltage fed back from the sense line L2. For example, the measurement circuit 370 compares the test voltage that is fed back from the sense line L2 with a target test voltage. The measurement circuit 370 increases the output voltage when the test voltage fed back is lower than the target test voltage and reduces the output voltage when the test voltage fed back is higher than the target test voltage. According to this, in a configuration in which the test voltage is supplied to the terminal of the device under test 10 via the pulse generation circuit 255, even when a resistance exists between the input end and the output end of the pulse generation circuit 255, the measurement circuit 370 can adjust the test voltage on the output end side of the pulse generation circuit 255 to be close to the target value.

In S530, the measurement circuit 370 measures a current which flows through the terminal of the device under test 10 in a state in which the test voltage is supplied to the terminal of the device under test 10. The measurement circuit 370 according to the present embodiment measures the current which flows through the terminal of the device under test 10 by using the resistance connected between the input end and the output end of the pulse generation circuit 255 as a sense resistance. In this case, the measurement circuit 370 measures a current which flows through the terminal of the device under test 10 by using a potential difference between the force line L1 and the sense line L2. For example, an internal resistance of the pulse generation circuit 255 when the output voltage of the measurement circuit 370 is caused to pass from the input end to output end is denoted as R, a voltage at the input end of the pulse generation circuit 255 which is measured by using the force line L1 is denoted as Vi, and a voltage at the output end of the pulse generation circuit 255 which is measured by using the sense line L2 is denoted as Vo. A current which flows through the terminal of the device under test 10 is substantially the same as a current which flows through the pulse generation circuit 255, and has a value obtained by dividing a potential difference (Vi-Vo) between the force line L1 and the sense line L2 by the internal resistance R. According to this, the voltage application current measurement test is performed by using the test voltage.

In accordance with the pin electronics apparatus 300 described above, the voltage application current measurement test of the device under test 10 can be performed via the pulse generation circuit 255 used for the functional test of the device under test 10. The measurement circuit 370 can measure the test voltage on the output end side of the pulse generation circuit 255 and adjust the output voltage. In addition, the measurement circuit 370 can calculate the current which flows through the terminal of the device under test 10 by using the internal resistance of the pulse generation circuit 255.

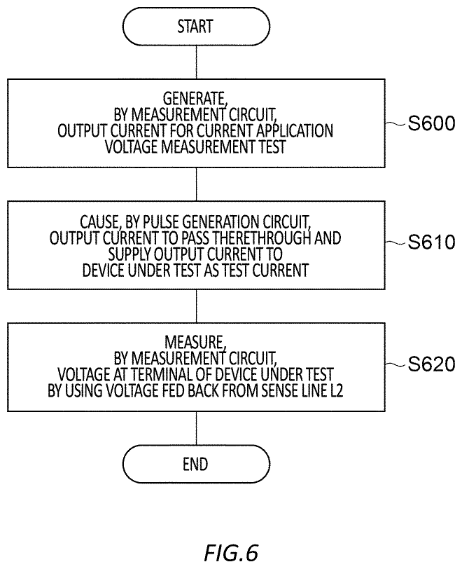

FIG. 6 illustrates an operational flow of the current application voltage measurement test of the device under test 10 by the testing apparatus 1 according to the present embodiment while focusing on an operation of the pin electronics apparatus 300. Before the present operational flow is started, the testing apparatus 1 electrically connects one or more pin electronics apparatuses 300 to the device under test 10 via the connection apparatus 120.

In S600, the measurement circuit 370 adjusts a current to be supplied to the device under test 10 to a test current. As an example, the measurement circuit 370 may generate the test current as an output current or may generate an output current for the current application voltage measurement test by factoring in a current which flows through a component other than the device under test 10 by splitting. According to this, the output current from the measurement circuit 370 becomes the test current to be supplied to the terminal of the device under test 10. The test current may be either a positive current or a negative current according to test content. In S610, the pulse generation circuit 255 causes the output current of the measurement circuit which is input from the measurement circuit 370 to pass therethrough and supplies this output current that has passed as a test current to the terminal of the device under test 10.

In S620, the measurement circuit 370 measures a voltage fed back from the sense line L2. The measurement circuit 370 may measure or calculate the voltage of the terminal of the device under test 10 by using the measured voltage. For example, when a wiring resistance from a connection point of the sense line L2 in a wiring from the output end of the pulse generation circuit 255 to the terminal of the device under test 10 to the terminal of the device under test 10 is negligible, the measurement circuit 370 may measure a voltage fed back from the sense line L2 as a voltage of the terminal of the device under test 10. When the wiring resistance from the connection point of the sense line L2 in the wiring from the output end of the pulse generation circuit 255 to the terminal of the device under test 10 to the terminal of the device under test 10 is taken into account, the measurement circuit 370 may calculate the voltage of the terminal of the device under test 10 by adding, to the measured voltage, a voltage drop (in the case of a positive current) or a voltage rise (in the case of a negative current) which is caused when the test current flows through a known wiring resistance. According to this, the current application voltage measurement test is performed by using the test current.

In accordance with the pin electronics apparatus 300 illustrated above, the current application voltage measurement test of the device under test 10 can be performed via the pulse generation circuit 255 used for the functional test of the device under test 10. The measurement circuit 370 can measure the voltage of the terminal of the device under test 10 on the output end side of the pulse generation circuit 255.

Note that in S600 and S610, the measurement circuit 370 may measure a current which flows through the terminal of the device under test 10 by using the potential difference between the force line L1 and the sense line L2 as illustrated in association with S530 in FIG. 5 and adjust the test current by using the measured current. For example, the measurement circuit 370 compares the measured current with a target test current. The measurement circuit 370 causes the output current to increase when the measured current is smaller than the target test current, and causes the output current to fall when the measured current is greater than the target test current. According to this, in a configuration in which the test current is supplied to the terminal of the device under test 10 via the pulse generation circuit 255, the measurement circuit 370 can adjust the test current to be close to the target value.

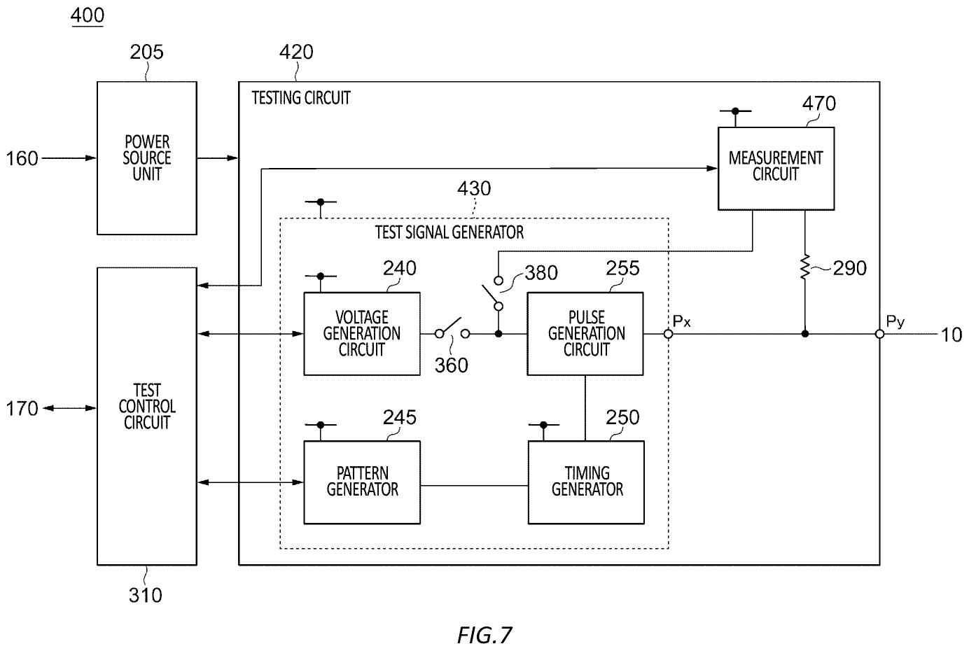

FIG. 7 illustrates a configuration of a pin electronics apparatus 400 according to a modified example. The pin electronics apparatus 400 is a modified example of the pin electronics apparatus 300. The testing apparatus 1 may include the pin electronics apparatus 400 instead of the pin electronics apparatus 200. The pin electronics apparatus 400 has the power source unit 205, a testing circuit 420, and the test control circuit 310. In this drawing, components with same reference numerals as those in FIG. 2 and FIG. 3 have similar functions and configurations to those in FIG. 2 and FIG. 3 and therefore will not be described below except for differences.

The testing circuit 420 is connected to the device under test 10 via the connection apparatus 120, receives power supply from the power source unit 205, and tests the device under test 10. This drawing illustrates a circuit portion corresponding to a single terminal of the device under test 10 in the testing circuit 420 in a representative manner. The testing circuit 420 may be connected to a plurality of terminals and have a circuit portion corresponding to each of the terminals.

The testing circuit 420 has a test signal generator 430 and a measurement circuit 470. The test signal generator 430 according to this modified example receives power supply from the power source unit 205 and control by the test control circuit 310 to perform the functional test of the device under test 10. The test signal generator 430 has the voltage generation circuit 240 similar to that illustrated in FIG. 2, the pattern generator 245, the timing generator 250, and the pulse generation circuit 255.

The measurement circuit 470 is connected at least between the voltage generation circuit 240 and the pulse generation circuit 255. The measurement circuit 470 may be each connected between the voltage generation circuit 240 and the pulse generation circuit 255 and between the pulse generation circuit 255 and the device under test 10. In this modified example, as an example, the measurement circuit 470 is connected between the voltage generation circuit 240 and the pulse generation circuit 255 and between the pulse generation circuit 255 and the device under test 10 via the force line L1 through which a voltage or a current is to be supplied to the device under test 10 and the sense line L2 through which a voltage of the device under test 10 is to be measured.

The force line L1 may be connected to the measurement circuit 470 and connected between the voltage generation circuit 240 and the pulse generation circuit 255. The force line L1 may function as an input end feedback line to feed back a voltage on an input end side of the pulse generation circuit 255 to the measurement circuit 470. In this case, the measurement circuit 470 may adjust an output voltage by using a voltage fed back from the force line in the functional test. Note that a resistance similar to the resistance 290 illustrated in FIG. 2 may be provided in the force line L1.

The sense line L2 may be connected to the measurement circuit 470 and connected between the pulse generation circuit 255 and the device under test 10. The sense line L2 may have a function similar to the sense line of the voltage illustrated in FIG. 2, and is connected to a connection point on a wiring between an output end of the pulse generation circuit 255 and the terminal of the device under test 10 and feeds back a voltage at this connection point to the measurement circuit 470. This connection point may be provided near the output end of the pulse generation circuit 255 in the test signal generator 330. Instead of this, this connection point may be provided outside the test signal generator 330 in the testing circuit 320, and for example, may be provided outside the testing circuit 320 near a terminal of the device under test 10 or the like. The resistance 290 having the function and the configuration similar to those of the resistance 290 illustrated in FIG. 2 may be provided in the force line L1.

The measurement circuit 470 adjusts a voltage or a current supplied to the device under test 10 in the parametric test (the voltage application current measurement test, the current application voltage measurement test, or the like) of the device under test 10 to a test voltage or a test current and performs the parametric test by using the test voltage or the test current.

The measurement circuit 470 according to this modified example may include a voltage supply unit and a current supply unit which are not illustrated in the drawing for generation of a voltage and a current to be supplied to the device under test 10. The measurement circuit 470 adjusts an output voltage and an output current generated from the voltage supply unit and the current supply unit and causes a test voltage or a test current to be supplied to the device under test 10.

The measurement circuit 470 may receive power supply from the power source unit 205 and control by the test control circuit 310. Although it may vary depending on a type of the supported parametric test, as an example, the measurement circuit 470 may further include various circuits including at least one of a voltage measuring instrument which measures a voltage output by the device under test 10, a current measuring instrument which measures a current output by the device under test 10, a frequency measuring instrument which measures a frequency of a signal output by the device under test 10, or the like.

The measurement circuit 470 according to this modified example may be possible to perform, as the parametric test, at least one of the voltage application current measurement test or the current application voltage measurement test. In the voltage application current measurement test, the measurement circuit 470 generates an output voltage and performs the voltage application current measurement test of the device under test 10 by using the output voltage. The output voltage of the measurement circuit 470 is supplied to the terminal of the device under test 10 as a test voltage via the pulse generation circuit 255. In the current application voltage measurement test, the measurement circuit 470 generates an output current and performs the current application voltage measurement test of the device under test 10 by using the output current. The output current of the measurement circuit 470 is supplied to the terminal of the device under test 10 as a test current via the pulse generation circuit 255. Herein, the output current of the measurement circuit 470 may be a positive current, that is, a current (source current) which flows towards the terminal of the device under test 10 from the measurement circuit 470 or may be a negative current, that is, a current (sink current) which flows towards the measurement circuit 470 from the terminal of the device under test 10.

Herein, the voltage generation circuit 240 in this modified example may be connected in series to the pulse generation circuit 255, and the first relay 360 may be provided between the voltage generation circuit 240 and the pulse generation circuit 255. The first relay 360 may be provided on the voltage generation circuit 240 side relative to a connection point with the force line L1 in the wiring between the voltage generation circuit 240 and the pulse generation circuit 255. The first relay 360 may be a mechanical relay or may be a semiconductor relay using a semiconductor switch or the like. The first relay 360 is turned on by the test control circuit 310 or the like when the functional test of the device under test 10 is performed, and connects the voltage generation circuit 240 and the pulse generation circuit 255. On the other hand, the first relay 360 is turned off by the test control circuit 310 or the like when the parametric test (the voltage application current measurement test, the current application voltage measurement test, or the like) of the device under test 10 by the measurement circuit 470 is performed, and disconnects the voltage generation circuit 240 and the pulse generation circuit 255.

In addition, the second relay 380 may be provided between the measurement circuit 470 and the point between the pulse generation circuit 255 and the voltage generation circuit 240. The second relay 380 may be provided in the force line L1 between the measurement circuit 470 and a connection point on the pulse generation circuit 255 side relative to the first relay 360 in a wiring between the pulse generation circuit 255 and the voltage generation circuit 240. The second relay 380 may be a mechanical relay or may be a semiconductor relay using a semiconductor switch or the like. The second relay 380 is turned off by the test control circuit 310 or the like when the functional test of the device under test 10 is performed, and disconnects the measurement circuit 470 and the pulse generation circuit 255. The second relay 380 is turned on by the test control circuit 310 or the like when the parametric test of the device under test 10 is performed, and connects the measurement circuit 470 and the pulse generation circuit 255.

The pulse generation circuit 255 according to the present embodiment and the terminal Py for the device under test 10 may be electrically and fixedly connected. Therefore, a relay configured to disconnect the connection, that is, for example, a relay (as an example, the relay 260 of FIG. 2) or the like configured to switch any of the functional test and the voltage application current measurement test or the current application voltage measurement test to be performed does not necessarily need to be present between the pulse generation circuit 255 and the terminal Py.

At least the measurement circuit 470 and the pulse generation circuit 255 in the testing circuit 420 described above may be provided on a common substrate. According to this modified example, as an example, each unit in the test signal generator 330 and the measurement circuit 470 may be provided on a common substrate and may be achieved by a single ASIC.

Note that the testing apparatus 1 according to the modified example described above may perform the functional test and the parametric test similarly as in the testing apparatus 1 according to the embodiment.

While the embodiments of the present invention have been described, the technical scope of the present invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the present invention.

The operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

1: testing apparatus;
10: device under test;
100: test head;
110: pin electronics apparatus;
120: connection apparatus;
150: main frame;
160: main power source apparatus;
170: control apparatus;
200: pin electronics apparatus;
205: power source unit;
210: test control circuit;
220: testing circuit;
230: test signal generator;
240: voltage generation circuit;
245: pattern generator;
250: timing generator;
255: pulse generation circuit;
260: relay;
270: measurement circuit;
280: relay;
290: resistance;
300: pin electronics apparatus;
310: test control circuit;
320: testing circuit;
330: test signal generator;
360: relay;
370: measurement circuit;
380: relay;
400: pin electronics apparatus;
420: testing circuit;
430: test signal generator;
470: measurement circuit;
L1: first line (force line); and
L2: second line (sense line).

What is claimed is:

1. A testing circuit comprising:
a voltage supply unit which generates an output voltage;
a pulse generation unit which generates a pulse signal by using the output voltage from the voltage supply unit in a functional test of a device under test and supplies the pulse signal to a device under test; and
a measurement circuit which adjusts a voltage or a current supplied to a device under test in a voltage application current measurement test or a current application voltage measurement test of a device under test to a test voltage or a test current and performs the voltage application current measurement test or the current application voltage measurement test by using the test voltage or the test current, wherein
the measurement circuit is connected at least between the voltage supply unit and the pulse generation unit.

2. The testing circuit according to claim 1, further comprising:
a connection terminal for a device under test, wherein
the pulse generation unit and the connection terminal are electrically and fixedly connected.

3. The testing circuit according to claim 1, further comprising a first relay provided between the voltage supply unit and the pulse generation unit.

4. The testing circuit according to claim 2, further comprising a first relay provided between the voltage supply unit and the pulse generation unit.

5. The testing circuit according to claim 1, further comprising a second relay provided between the measurement circuit and a point between the pulse generation unit and the voltage supply unit.

6. The testing circuit according to claim 2, further comprising a second relay provided between the measurement circuit and a point between the pulse generation unit and the voltage supply unit.

7. The testing circuit according to claim 3, further comprising a second relay provided between the measurement circuit and a point between the pulse generation unit and the voltage supply unit.

8. The testing circuit according to claim 4, further comprising a second relay provided between the measurement circuit and a point between the pulse generation unit and the voltage supply unit.

9. The testing circuit according to claim 1, wherein the measurement circuit is connected between the voltage supply unit and the pulse generation unit and connected between the pulse generation unit and a device under test via a first line for supply of a voltage or a current to a device under test and a second line for measurement of a voltage of a device under test.

10. The testing circuit according to claim 2, wherein the measurement circuit is connected between the voltage supply unit and the pulse generation unit and connected between the pulse generation unit and a device under test via a first line for supply of a voltage or a current to a device under test and a second line for measurement of a voltage of a device under test.

11. The testing circuit according to claim 3, wherein the measurement circuit is connected between the voltage supply unit and the pulse generation unit and connected between the pulse generation unit and a device under test via a first line for supply of a voltage or a current to a device under test and a second line for measurement of a voltage of a device under test.

12. The testing circuit according to claim 4, wherein the measurement circuit is connected between the voltage supply unit and the pulse generation unit and connected between the pulse generation unit and a device under test via a first line for supply of a voltage or a current to a device under test and a second line for measurement of a voltage of a device under test.

13. The testing circuit according to claim 5, wherein the measurement circuit is connected between the voltage supply unit and the pulse generation unit and connected between the pulse generation unit and a device under test via a first line for supply of a voltage or a current to a device under test and a second line for measurement of a voltage of a device under test.

14. The testing circuit according to claim 6, wherein the measurement circuit is connected between the voltage supply unit and the pulse generation unit and connected between the pulse generation unit and a device under test via a first line for supply of a voltage or a current to a device under test and a second line for measurement of a voltage of a device under test.

15. The testing circuit according to claim 9, wherein the second line is connected between the pulse generation unit and a device under test and connected to the measurement circuit.

16. The testing circuit according to claim 1, wherein the voltage supply unit and the pulse generation unit are connected in series.

17. The testing circuit according to claim 1, wherein the voltage supply unit, the pulse generation unit, and the measurement circuit are provided on a common substrate.

18. The testing circuit according to claim 1, wherein the measurement circuit adjusts the test voltage or the test current by using a voltage supplied from the voltage supply unit.

19. A testing apparatus comprising the testing circuit according to claim 1.

20. A testing method comprising:
generating, by a pulse generation circuit, a pulse signal by using an output voltage from a voltage supply unit in a functional test of a device under test and supplying the pulse signal to a device under test; and
adjusting, by a measurement circuit connected at least between the voltage supply unit and the pulse generation circuit, a voltage or a current supplied to a device under test in a voltage application current measurement test or a current application voltage measurement test of a device under test to a test voltage or a test current and performing the voltage application current measurement test or the current application voltage measurement test by using the test voltage or the test current.
